(19) United States
(12) Patent Application Publication
(10) Pub. No.: US 2024/0105677 A1
(43) Pub. Date: Mar. 28, 2024

(54) RECONSTITUTED WAFER WITH SIDE-STACKED INTEGRATED CIRCUIT DIE

(71) Applicant: Intel Corporation, Santa Clara, CA (US)

(72) Inventors: Abhishek Anil Sharma, Portland, OR (US); Tahir Ghani, Portland, OR (US); Sagar Suthram, Portland, OR (US); Anand Murthy, Portland, OR (US); Wilfred Gomes, Portland, OR (US); Pushkar Ranade, San Jose, CA (US)

(73) Assignee: Intel Corporation, Santa Clara, CA (US)

(21) Appl. No.: 17/955,269

(22) Filed: Sep. 28, 2022

(51) Int. Cl. H01L 25/065; H01L 23/00; H01L 23/427; H01L 25/00

(52) U.S. Cl. CPC H01L 25/0655; H01L 23/427; H01L 24/08; H01L 24/80; H01L 25/50; H01L 24/32; H01L 2224/08145; H01L 2224/32221; H01L 2224/80895; H01L 2224/80896

(57) ABSTRACT

An integrated circuit device includes a first IC die with a first front surface, a first back surface, and a first side surface along opposed edges of the first front surface and the first back surfaces of the first IC die, a second IC die with a second front surface, a second back surface, and a second side surface along opposed edges of the second front surface and second back surface of the second IC die, a substrate coupled to the first side surface of the first IC die and the second side surface of the second IC die, and fill material between one of the first front surface and the first back surface of the first IC die and one of the second front surface and second back surface of the second IC die. Other embodiments are disclosed and claimed.

### BACKGROUND

A reconstituted wafer refers to a wafer that has many individual integrated circuit (IC) die or chips on the wafer covered by a molded compound. Redistribution layers (RDLs) may be formed in polymer layers of the mold compound and configured to provide either fan-in or fan-out packaging for each of the chip packages. The reconstituted wafer is then diced to separate the individual chip packages.

There is an ongoing need for improved computational devices to enable ever increasing demand for modeling complex systems, providing reduced computation times, and other considerations. In some contexts, scaling features of integrated circuits has been a driving force for such improvements. Other advancements have been made in materials, device structure, circuit layout, and so on. In particular, there is an ongoing desire to improve wafers that are utilized for in or otherwise support operation of integrated circuits. It is with respect to these and other considerations that the present improvements have been needed. Such improvements may become critical as the desire to improve computational efficiency become even more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIG. 1 illustrates a block diagram side view of an example integrated circuit (IC) device that includes one or more side-stacked IC die (SSICs);

FIG. 2 illustrates a block diagram side view of another example of an IC device that includes one or more SSICs;

FIG. 3 illustrates a block diagram of an example of a system;

FIGS. 4A to 41 illustrate cross sectional side views of another example of an IC device that includes SSICs at various process steps;

FIG. 5 illustrates a block diagram partial side view of another example of an IC device that includes SSICs;

FIG. 6A illustrates a block diagram partial perspective view of another example of an IC device that includes SSICs;

FIG. 6B illustrates a block diagram partial perspective view of another example of an IC device that includes SSICs;

FIG. 7 illustrates a cross-sectional view of a low-temperature IC system, using die- and package-level active cooling;

FIG. 8 illustrates a view of an example two-phase immersion cooling system for low-temperature operation of an IC device;

FIGS. 9A to 9D illustrates various processes or methods for forming SSICs on an IC device;

FIG. 10 illustrates a diagram of an example data server machine employing an IC device with SSICs; and

FIG. 11 is a block diagram of an example computing device, all in accordance with at least some implementations of the present disclosure.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure. The term “aligned” (i.e., vertically or laterally) indicates at least a portion of the components are aligned in the pertinent direction while “fully aligned” indicates an entirety of the components are aligned in the pertinent direction.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking, or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to improve reconstituted wafers for integrated circuits (ICs). One problem with reconstituted wafers is that there is limited surface area on the reconstituted wafer for IC die. Another problem with conventional reconstituted wafers is that no connections are made between IC die on the reconstituted wafer. Some embodiments may overcome one or more of the foregoing problems. Some embodiments may provide technology for side-stacked IC die on a reconstituted wafer (e.g., sometimes referred to herein as a tilt-processed reconstituted wafer). Advantageously, because the sidewall surface area is smaller than the front and back side surface area, more IC die may be provided on the tilt-processed reconstituted wafer. Some embodiments may provide technology to interconnect two or more die on the tilt-processed reconstituted wafer. Advantageously, the tilt-processed reconstituted wafer may be utilized whole as a wafer-scale engine or may be diced into super-die that include two or more interconnected, side-stacked IC die. In some embodiments, one or more wafers for an IC device that includes a tilt-processed reconstituted wafer are round. In some embodiments, one or more wafers for an IC device that includes a tilt-processed reconstituted wafer are square or rectangular. Some embodiments may advantageously enable very high density processing devices. Some embodiments may further be cooled to operate at very low temperatures, which may be particularly beneficial for very high density processing devices.

Some embodiments may provide a tilt-processed reconstituted wafer, where individual IC die in the reconstituted wafer are turned on their respective sides. Some embodiments may involve sidewall processing of stacked side-planarized wafers. In some embodiments, sidewall processing may be added to a low temperature CMOS process (e.g., used to provide a tilt-processed reconstituted wafer) using one or more of a prebuild layer transfer process, a hybrid bonding process, and a thin film process. In some embodiments, transistors in the low temperature CMOS process may be CMOS transistors or low temperature thin film transistors (TFTs). Some embodiments advantageously provide routing signals across the reconstituted wafer between individual side-stacked IC die. In some embodiments, silicon carbon oxynitride (SiCON) films or a SiCON layer may be formed between the side-stacked IC die and other layers/circuits bonded to the side-stacked IC die.

Some embodiments of IC devices, systems, circuits, and techniques described herein are related to SSIC devices for ultra-low voltage operation. Such SSIC devices may be operable at very low temperatures for improved device performance and/or they may be integrated with complementary metal oxide semiconductor field effect transistors (CMOS FETs) such as FinFETs, nanosheet transistors, etc.

Techniques discussed herein may also provide advantageous SSIC devices for low voltage applications. In some embodiments, such applications may also be deployed at very low temperatures, such as, at or below 0° C. For example, the SSIC devices may be deployed in an IC device including or coupled to cooling structure operable to remove heat from the IC device to achieve an operating temperature at the very low temperature. As used herein, the term cooling structure or active cooling structure indicates a device that uses power to provide cooling (e.g., via flow of a coolant, immersion in a coolant, etc.). Notably, the cooling structure or active cooling structure need not be in operation to be labeled as such. The active cooling structure may be part of the IC device, provided separate from the IC device, or both. In some contexts, an active cooling structure is not needed as the IC device is deployed in a very low temperature environment such as in any of a subpolar oceanic climate, a subarctic climate, an arctic climate, a tundra climate, an ice cap climate, or any other environment of sustained cold temperatures.

In some embodiments, a SSIC device includes high density processing circuitry. At room temperatures, such circuitry may exhibit efficiency behavior that significantly limits the utility of such circuitry in a SSIC device. However, at very low temperatures, such materials exhibit much better efficiency characteristics. For example, at very low temperatures, a SSIC device may be constructed with very high density processing circuitry.

In deployment at very low temperatures, SSIC devices using such high density circuitry may have better controlled power requirements and exceptional performance. Therefore, such SSIC devices may advantageously be deployed as various circuits/devices including wafer-scale processors, wafer-scale engines, etc. In some embodiments, the SSIC devices are used at very low voltage. In some implementations, the term very low voltage indicates a voltage of not more than 50 mV, although lower voltages may be used such as voltages of not more than 10 mV. In some embodiments, the SSIC devices are integrated with CMOS FETs such as CMOS FinFETs, nanosheet transistors, etc. Notably, after fabrication of the SSIC devices over a first substrate, the SSIC devices may be layer transferred to a second substrate such as a silicon substrate and the CMOS FETs may be fabricated in an exposed portion of the silicon substrate either on the same side as the SSIC devices or on an opposite side of the SSIC devices. The SSIC devices and CMOS FETs are then integrated into circuits that advantageously use both devices at very low temperature.

As discussed, an IC device including SSIC die and CMOS FETs may be deployed in a very low temperature context. In some embodiments, the operating temperature of the IC device is maintained at or below 0° C. In some embodiments, the operating temperature of the IC device is maintained at or below about −196° C. (i.e., using liquid nitrogen as the coolant). In some embodiments, the operating temperature of the IC device is maintained at or below about −25° C. In some embodiments, the operating temperature of the IC device is maintained at or below about −50° C. In some embodiments, the operating temperature of the IC device is maintained at or below about −70° C. In some embodiments, the IC device is maintained at or below about −100° C. Other temperatures may be used based on coolant, environment, and so on. Other temperatures may be used based on coolant, environment, and so on. In operation at such very low temperatures, the SSIC die become more efficient and the CMOS FETs see a substantial boost in performance relative to operation at higher temperatures inclusive of increased carrier mobility, reduced contact resistance, and reduced leakage.

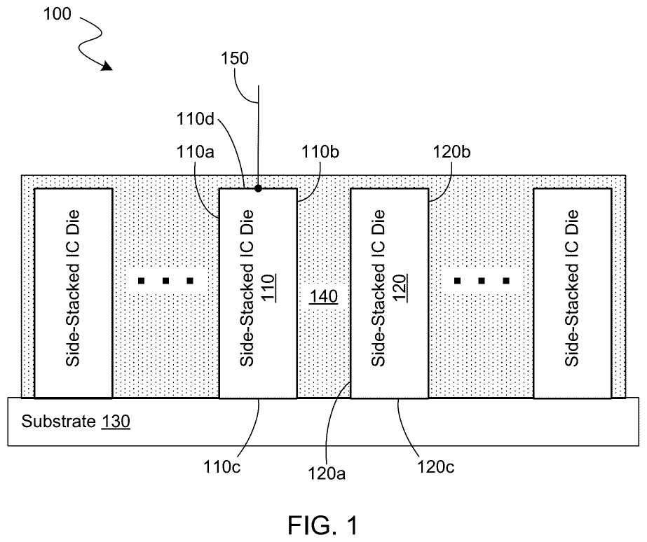

FIG. 1 shows an illustrative block diagram side view of an example IC device 100 that includes at least two side-stacked IC die in accordance with some embodiments. In FIG. 1, the IC device 100 includes a first IC die 110 with a first front surface 110a, a first back surface 110b, and a first side surface 110c along opposed edges of the first front surface 110a and the first back surfaces 110b of the first IC die 110, a second IC die 120 with a second front surface 120a, a second back surface 120b, and a second side surface 120c along opposed edges of the second front surface 120a and second back surface 120b of the second IC die 120, and a substrate 130 coupled to the first side surface 110c of the first IC die 110 and the second side surface 120c of the second IC die 120.

In various embodiments of the IC device 100, the first IC die 110 and second IC die 120 may have any suitable arrangement including, for example, front-to-back, front-to-front, or back-to-back. The IC device 100 further includes with fill material 140 between the facing surfaces of the one or more side-stacked IC die (e.g., the fill material 140 may be between one of the front and back surfaces of the first IC die 110 and one of the front and back surfaces of the second IC die 120). In FIG. 1, the fill material 140 is between the first back surface 110b of the first IC die 110 and the second front surface 120a of the second IC die 120. The IC device 100 may further include a first electrical connection 150 through a third side surface 110d along opposed edges of the first front surface 110a and the first back surface 110b of the first IC die 110 opposite to the first side surface 110c of the first IC die 110 (e.g., that is coupled to the substrate 130).

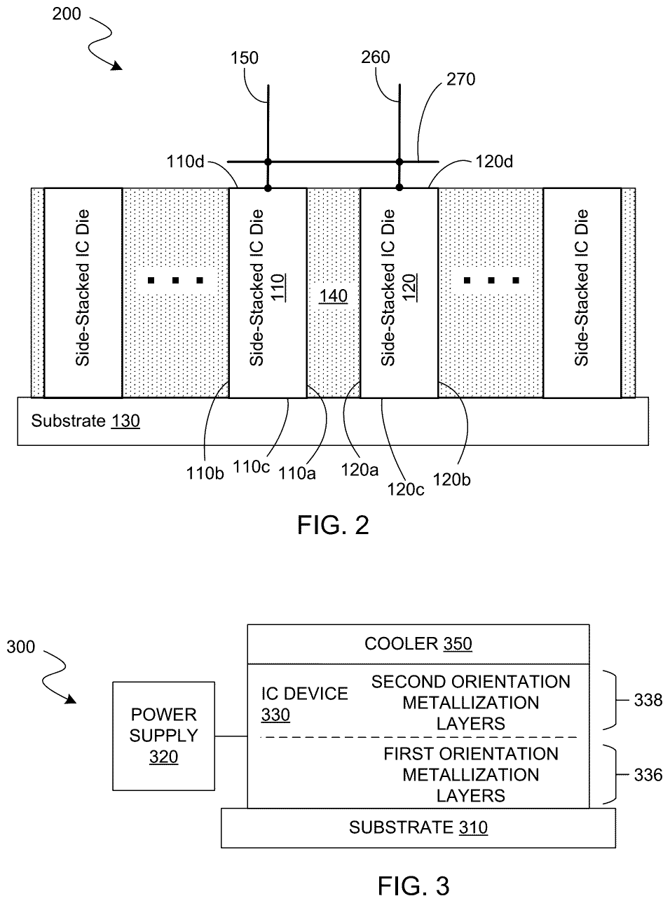

FIG. 2 shows an illustrative block diagram side view of an example IC device 200 that includes one or more side-stacked IC die in accordance with some embodiments. The IC device 200 includes similar elements as the IC device 100, with similar elements indicated by like reference numerals. In FIG. 2, the first IC die 110 and the second IC die 120 are re-arranged front-to-front and the fill material 140 is between the first front surface 110a of the first IC die 110 and the second front surface 120a of the second IC die 120. The IC device 200 may further include a second electrical connection 260 through a fourth side surface 120d along opposed edges of the second front surface 120a and the second back surface 120b of the second IC die 120 opposite to the second side surface 120c of the second IC die 120 (e.g., that is coupled to the substrate 130), and conductive material 270 (e.g., a metallization structure) over the third side 110d of the first IC die 110 and the fourth side 120d of the second IC die 120 that couples the first electrical connection 150 to the second electrical connection 260.

In some embodiments, the conductive material 270 may be layer transferred over the third side 110d of the first IC die 110 and the fourth side 120d of the second IC die 120. In some embodiments, the conductive material 270 may be hybrid bonded over the third side 110d of the first IC die 110 and the fourth side 120d of the second IC die 120. In some embodiments, the conductive material 270 may be thin film processed over the third side 110d of the first IC die 110 and the fourth side 120d of the second IC die 120.

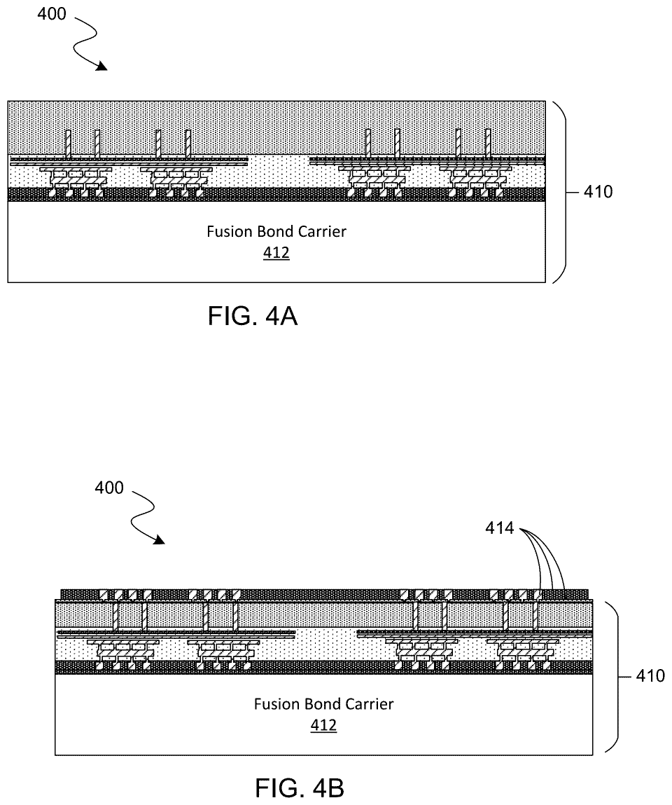

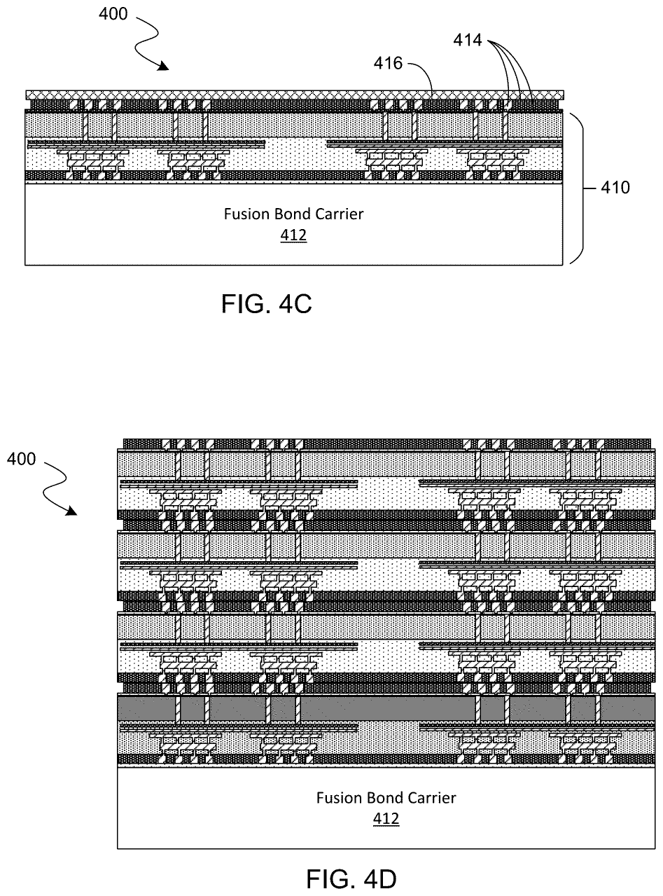

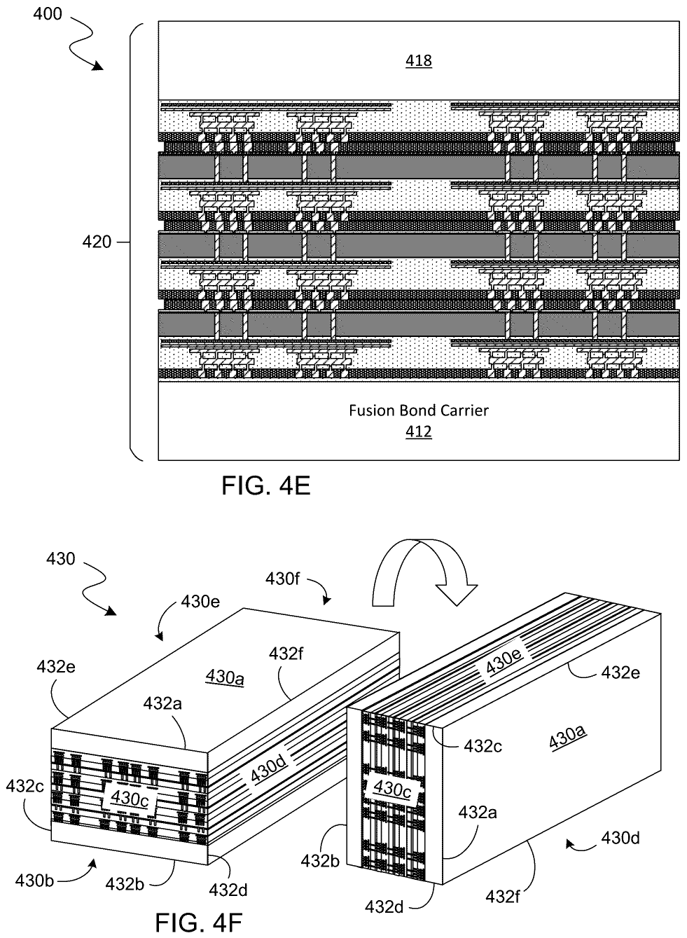

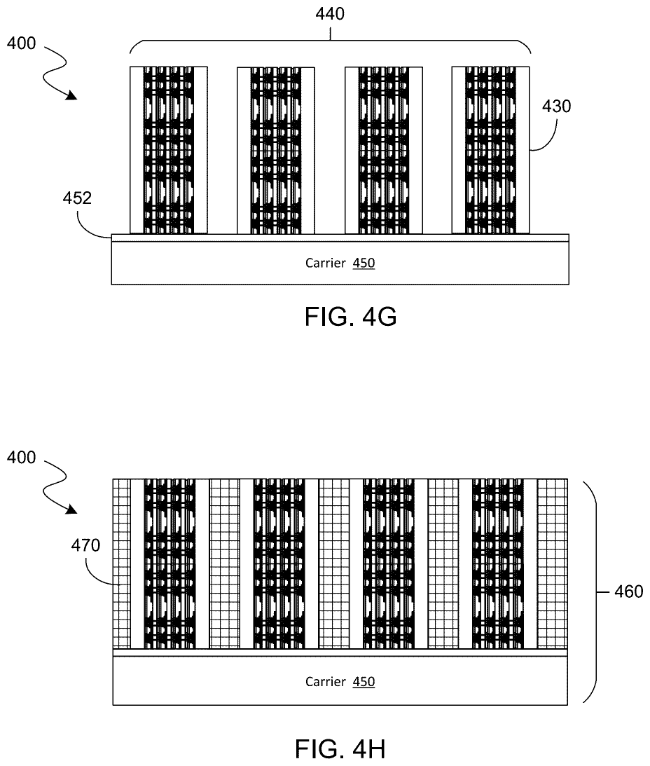

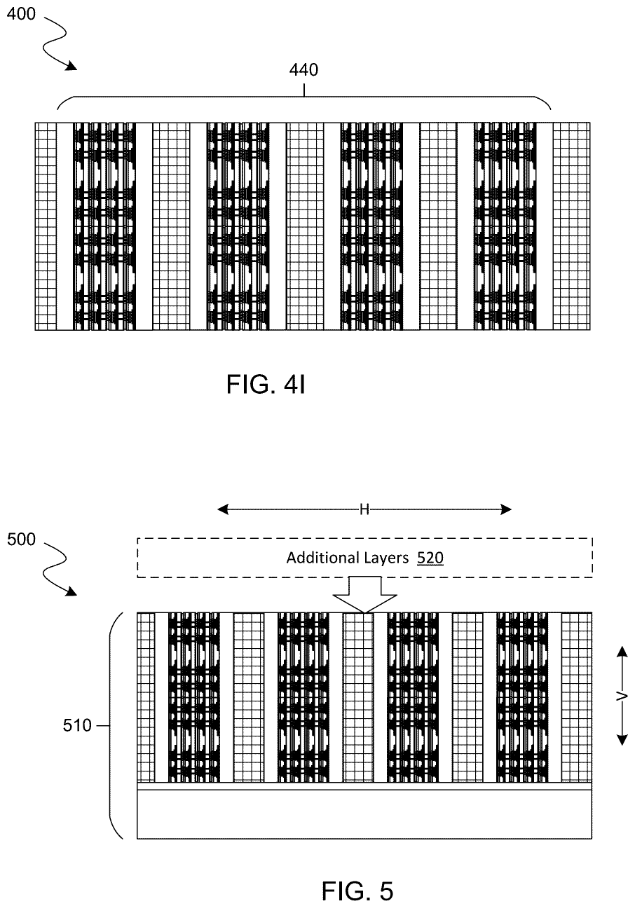

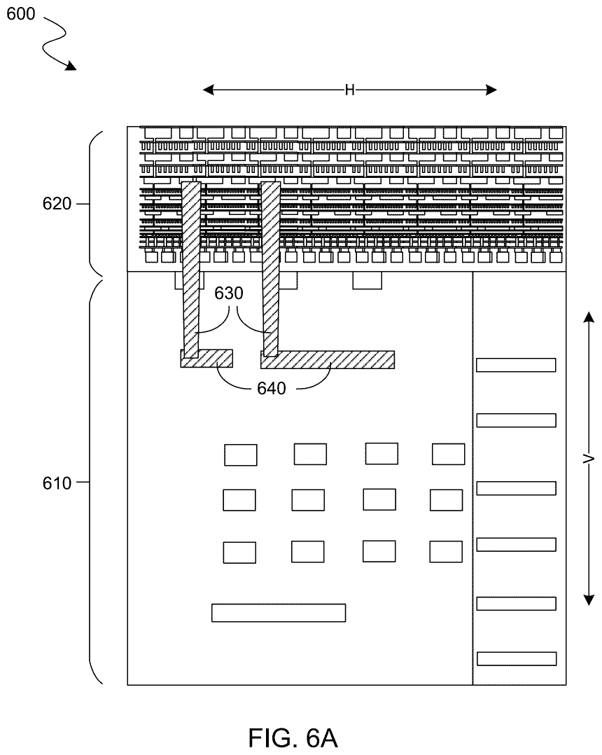

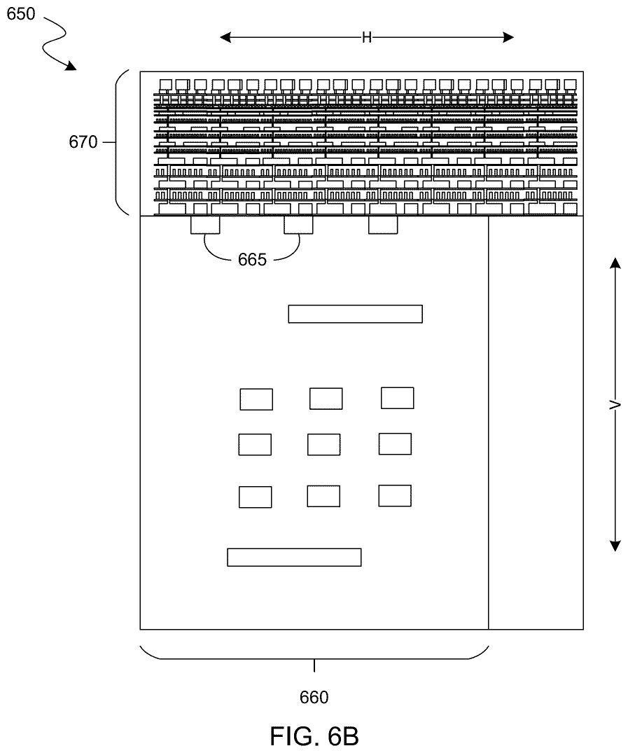

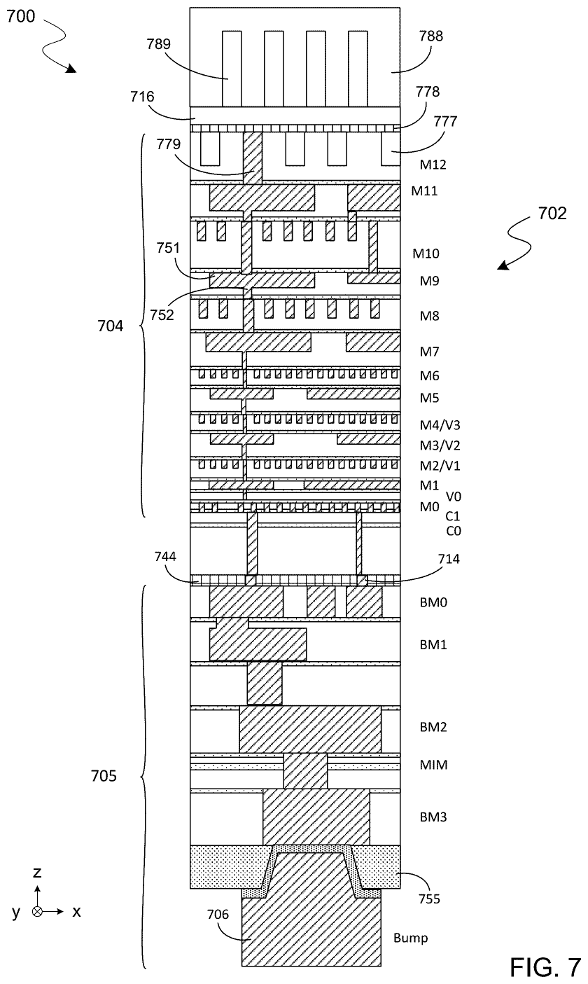

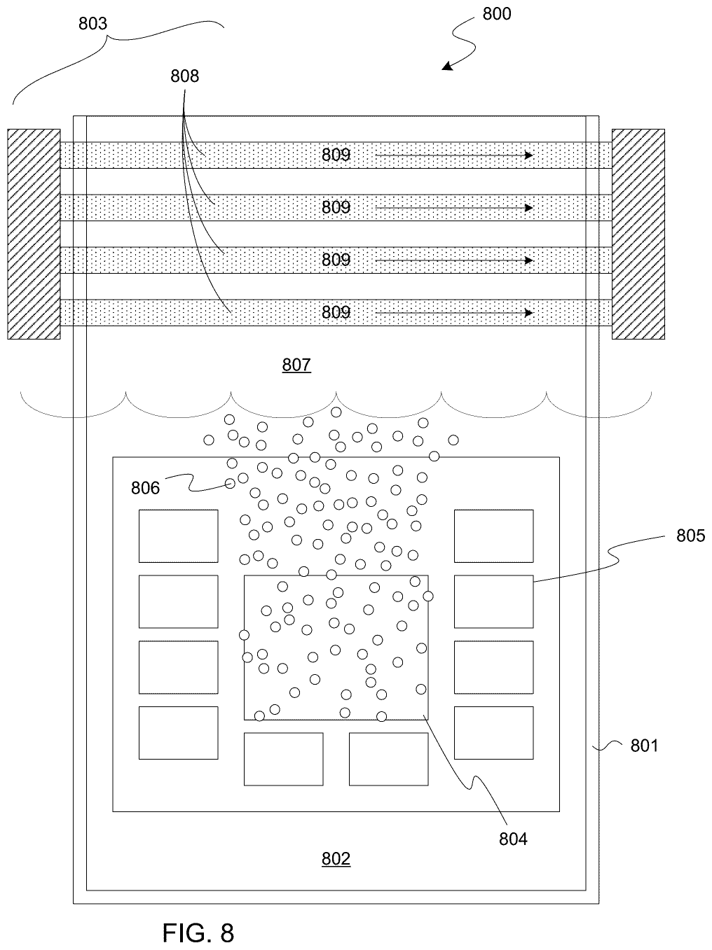

FIG. 3 shows a block diagram view of an example of a system 300 that includes a substrate 310, a power supply 320, and an IC device 330 attached to the substrate 310 and coupled to the power supply 320. In various embodiments, the IC device 330 may be an IC die, a super-die, a wafer-scale IC device, etc. The IC device 330 may be similarly configured as any of the various ICs described herein including, for example, the IC device 100 (FIG. 1), IC device 200 (FIG. 2), the IC device 400 (FIG. 4), the IC device 500 (FIG. 5), the IC device 600 (FIG. 6A), the IC device 650 (FIG. 6B), and IC device 702 (FIG. 7). Any suitable substrate technology may be utilized for the substrate 310 including, for example, the substrates described herein in connection with FIGS. 7 and 8 (e.g., substrate 805). In some embodiments, the IC device 330 may be coupled to the power supply 320 through the substrate 310.

In some embodiments, the IC device 330 may include a plurality of SSIC devices as described herein. For example, the IC device 330 may include two different orientations of signal routing and metal lines with first orientation metallization layers 336 under second orientation metallization layers 338 (e.g., where the second orientation is perpendicular to the first orientation). For example, the first orientation metal layers 336 may include SSICs with a vertical orientation of the metal layers while the second orientation metal layers 338 may include additional metal layers with a horizontal orientation bonded to the first orientation metal layers 336.

In some embodiments, the IC device 330 may comprises a tilt-processed reconstituted wafer with a plurality of IC die coupled to the substrate of the reconstituted wafer on respective first sidewalls of the plurality of IC die (e.g., including the first orientation metallization layers 336), and one or more interconnect layers (e.g., including the second orientation metallization layers 338) over the reconstituted wafer, where the one or more interconnect layers provide one or more electrical connections between two or more IC die of the plurality of IC die through respective second sidewalls of the plurality of IC die opposite to the first sidewalls. For example, the one or more interconnect layers may be layer transferred over the reconstituted wafer, hybrid bonded over the reconstituted wafer, or thin film processed over the reconstituted wafer. In some embodiments, the IC device 330 may comprise a wafer-scale engine.

The system 300 further includes a cooler 350 thermally coupled to the IC device 330 (e.g., over the IC device 330). In some embodiments, the cooler 350 provides a cooling structure operable to remove heat from the IC device 330 to achieve an operating temperature at or below 0° C. For example, the IC device 330 may comprise the second orientation metallization layers 338 over the plurality of SSIC devices, the metallization layers to provide signal routing for the plurality of SSIC devices, and the cooler 350 may be over the second orientation metallization layers 338. In some embodiments, the cooler 350 may comprise comprises a plurality of microchannels in the IC device 330 (e.g., and over the reconstituted wafer that includes the first orientation metallization layers 336), the microchannels to convey a heat transfer fluid therein. In some embodiments, the cooler 350 may further comprise a mounted to the IC device 330 over the microchannels, the chiller comprising one of a solid body comprising second microchannels to convey a second heat transfer fluid therein or a heat sink for immersion in a low-boiling point liquid. In some embodiments, the cooler 350 may be operable to remove heat from the IC device 330 to achieve an operating temperature at or below about −25° C. In some embodiments, the cooler 350 may be configured to convey liquid nitrogen to achieve an operating temperature at or below about −196° C.

FIGS. 4A to 41 show illustrative partial, cross sectional side views of an example of an IC device 400 at various process steps. In this example, the finished IC device 400 may be a tilt-processed reconstituted wafer that includes SSIC die. These process steps may be implemented for silicon and non-silicon technologies. In FIG. 4A, a full thickness (e.g., about 700 um) wafer 410 (e.g., with RDL layers patterned on the wafer 410) is face down fusion bonded on a carrier wafer 412. For example, after the wafer 410 with front-side and back-side processing is completed, the finished wafer 410 is face-to-face bonded on the carrier wafer 412. In FIG. 4B, the wafer 410 is thinned down and planarized to reveal TSVs and more layers (e.g., dielectric layers, metal layers, etc.) are added to the back-side of the wafer 410. In this example, bonding layer(s) 414 are created on the back-side of the wafer 410. In FIG. 4C, an optional oxide layer 416 is deposited on the bonding layer 414 (e.g., if no further hybrid bonding of additional layers is needed). In FIG. 4D, additional material layers (e.g., dielectric layers, metal layers, etc.) are added. For example, the steps of FIG. 4A (bonding) and FIGS. 4B and 4C (TSV reveal, bonding layer creation) may be repeated any number of times (e.g., generally between five and ten times). In FIG. 4E, another wafer 418 is bonded over the entire layer stack to create a composite wafer 420 that is relatively thick (e.g., over one millimeter and up to several millimeters).

In FIG. 4F, the composite wafer 420 is cut into smaller die that may be referred to as stacklets. A stacklet 430 may have a general cube shape with six surfaces including a front surface 430a, a back surface 430b, and four side surfaces 430c, 430d, 430e, and 430f. In some embodiments, one side surface 430c may have edges 432a, 432b along the front and back surfaces 430a, 430b that are longer than edges 432c, 432d between the front and back surfaces 430a, 430b (e.g., where the length of the edges 432c, 432d corresponds to a thickness of the stacklet). Another side surface 430d that shares an edge 432d with the side surface 430c may have edges 432e, 432f along the front and back surfaces 430a, 430b that are longer than the edges 432a, 432b (e.g., several times larger), such that, when the stacklet 430 is flipped on the side surface 430d, the stacklet 430 is taller (e.g., along vertical edges 432a, 432b) than the stacklet is wide (e.g., along horizontal edges 432c, 432d), and relatively long (e.g., along edges 432e, 432f). Non-limiting example ranges include a thickness of about 1 to 3 mm (e.g., for edge 432c), a height of about 3 to 7 mm (e.g., for edge 432a), and a length of about 10 to 30 mm (e.g., for edge 432e). Relatively long stacklets may be readily handled manually and/or with automated equipment. In some embodiments, the side surface 430d may be utilized as a mounting surface for a tilt-processed reconstituted wafer, while the opposite side surface 430e may be utilized as a bonding surface and/or for sidewall processing.

In FIG. 4G, one or more stacklets 440 (e.g., including stacklet 430) are stacked vertically on a carrier wafer 450 (e.g., a blank wafer, a blanket wafer, etc.), with respective mounting sides of the stacklets 440 against the carrier wafer 450, and are affixed to the carrier wafer 450. Any suitable techniques may be utilized to position the stacklets and affix them to the carrier wafer 450 with a suitable amount of space between respective stacklets 440. In some embodiments, a chemical mechanical polishing (CMP) process may be utilized to prepare a top bonding surface of the carrier wafer 450. In some embodiments, one or more bonding layers 452 may be deposited on the top bonding surface of the carrier wafer 450 for bonding/adhering the stacklets 440 to the carrier wafer 450.

One or more of the other stacklets 440 may be from the same composite wafer 420 as the stacklet 430. One or more of the stacklets 440 may be from a different composite wafer as the stacklet 430. One or more of the stacklets 440 may have the same circuitry thereon as other ones of the stacklets 440. One or more of the stacklets 440 may have different circuitry thereon as other ones of the stacklets 440. For a wafer-scale engine, for example, a wide variety and large number of IC devices with appropriate functionality may be included on the carrier wafer 450 to implement the wafer-scale engine.

In FIG. 4H, the IC device 400 is reconstituted with the side-stacked stacklets 440 to create a solid, tilt-processed reconstituted wafer 460 with fill material 470 between the stacklets 440. Any suitable techniques and materials may be utilized to gap fill and encapsulate the stacklets 440 and create the solid reconstituted wafer 460 including any of a variety of epoxies, polymers, fillable oxides, etc. After the gaps are all filled, the reconstituted wafer 460 may be planarized and/or polished (e.g., with a CMP process) to remove excess fill material. During the polishing, in some embodiments, metal lines or other metallization structures in the sidewalls of the stacklets 440 may be exposed for further connectivity. In FIG. 4I, the other side of the reconstituted wafer 460 may also be planarized/polished to expose metal lines or metallization structures on both sidewalls of the stacklets 440 for further processing/connectivity. After planarizing the first surface (FIG. 4H), for example, the reconstituted wafer 460 may be flipped to planarize the other side of the stacklets 440 as well. In some embodiments, the polishing/planarizing does not need to expose any sidewall metal because TSVs or other techniques may be utilized to connect to metallization structures within the stacklets 440 through the sidewalls of the stacklets 440. In some embodiments, the IC device 400 may include the whole tilt-processed, reconstituted wafer to be utilized as a wafer-scale IC device. In some embodiments, the IC device 400 may be diced (e.g., re-singulated as individual IC die, a super-die, etc.). In some embodiments, the vertical edges of the die/super-die may be planarized to expose metallization structures along the vertical edges that may then be hybrid bonded to other devices/packages.

FIG. 5 shows a block diagram partial side view of an example of an IC device 500 that includes SSICs. A tilt-processed, reconstituted wafer 510 may be similarly configured as the reconstituted wafer 460 (FIG. 4H). For example, one or more full wafers may be processed and stacked utilizing any suitable technology (e.g., hybrid bonding). The full wafer is then singulated into individual IC die (e.g., which may be interchangeably referred to herein as chiplets, stacklets, or IC die). The stacklets are then side-mounted to a base wafer and back-filled with any suitable material to form the reconstituted wafer 510. The top surface of the reconstituted wafer is appropriately prepared (e.g., planarized and/or polished), and one or more additional layers 520 of material (e.g., dielectrics, metals, etc.) are then added over the reconstituted wafer 510 to provide connectivity between the side-mounted stacklets through respective sidewalls of the stacklets (e.g., with suitable sidewall processing). For example, a backend oxide or transition metal dichalcogenide or poly/single-crystal—Si, Ge, SiGe, III-V, etc. may be added that includes transistors that provide connectivity across the reconstituted wafer 510.

In the device 500, there are two distinct orientations of metal lines in a single package. The original horizontal orientation of metal lines in the stacklets becomes a vertical orientation of metal lines (e.g., indicated by the arrow V) in the device 500 while the subsequently added layers have a horizontal orientation of metal lines (e.g., indicated by the arrow H). In respective embodiments, the additional layers 520 may be added by hybrid bonding another pre-processed wafer over the reconstituted wafer 510, by layer transferring material over the reconstituted wafer 510, and/or by otherwise depositing metal layers or thin film transistor layers over the reconstituted wafer 510 (e.g., all of which may be done after appropriate preparation of the top bonding surface of the reconstituted wafer 510). Any suitable techniques may be utilized to add, form, grow, or deposit the additional layers 520 of material including, for example, atomic layer deposition (ALD), chemical vapor deposition (CVD), and plasma vapor deposition (PVD).

In some embodiments, holes may be drilled, etched, or otherwise formed through the sidewalls of the stacklets and filled with metal to make vias for further connectivity as needed between the additional layers 520 and the stacklets of the reconstituted wafer 510. Advantageously, the additional layers 520 may provide complicated connections (e.g., together with additional logic/circuitry) to create a connection matrix across the reconstituted vertical stacklets of the reconstituted wafer 510.

In some embodiments, the IC device 500 may include the whole tilt-processed, reconstituted wafer 510 with the suitably bonded additional layers 520 to be utilized as a wafer-scale IC device. In some embodiments, the reconstituted wafer 510 with the suitably bonded additional layers 520 may be diced (e.g., re-singulated as respective individual IC die, respective super-die, etc.). In some embodiments, the vertical edges of the die/super-die may be planarized to expose metallization structures along the vertical edges that may then be hybrid bonded to other devices/packages.

FIG. 6A shows a block diagram partial perspective view of an example of an IC device 600 that includes SSICs. In some embodiments, one or more layers 620 of suitable material are bonded over a tilt-processed reconstituted wafer 610 (e.g., either layer transferred or deposited) and one or more through-vias 630 (e.g., through-silicon vias (TSVs) are formed in the one or more layers 620 over the reconstituted wafer 610 and through the sidewalls of the stacklets. Any suitable techniques may be utilized to form the through-vias 630 such that they hit appropriate metallization structure(s) 640 through the sidewall of a stacklet. For example, the stacklet may be formed with one or more suitable vertical metallization structures that, when the stacklet is turned on its side, become one or more suitable horizontal metallization structures for subsequent contact with one or more through-vias. For example, the metallization structures in the stacklet provide suitably flat profiles for a connection to through-vias through the sidewall of the stacklet.

In some embodiments, the metallization structures for subsequent contact with through-vias are formed in middle layers of the stacklet (e.g., with some suitable clearance from the front and back surfaces of the stacklet. In some embodiments, the through-vias may make the connection at any suitable depth through the sidewall of the stacklet. Further metallization structures formed in or over the one or more layers 620 over the reconstituted wafer 610 may provide connections between the through-vias to electrically connect two or more stacklets in the reconstituted wafer. The one or more layers 620 over the reconstituted wafer 610 may further include logic or other circuitry, including die-to-die interface circuitry. In the device 600, there are two distinct orientations of metal lines in a single package. The original horizontal orientation of metal lines in the stacklets becomes a vertical orientation of metal lines (e.g., indicated by arrow V) in the device 600 while the subsequently bonded layers have a horizontal orientation of metal lines (e.g., indicated by arrow H).

FIG. 6B shows a block diagram partial perspective view of an example of an IC device 650 that includes SSICs. In some embodiments, one or more IC devices 670 (e.g., IC die, super-die, a full wafer, etc.) are hybrid bonded to side-mounted stacklets 660. For example, the stacklets 660 may be formed with one or more suitable metallization structures 665 at their respective bonding sides and the bonding sides may be polished to remove enough material over the side-mounted stacklets 660 to expose the metallization structures 665 on the bonding side of the stacklets 660. The exposed metallization structures on the sidewalls of the stacklets 660 provide suitable bonding pads to be hybrid bonded to the IC devices 670 over the stacklets 660 and make connections between the stacklet 660 and other stacklets (e.g., for complicated interconnects, high density processing, etc.). In some embodiments, bumps or other hybrid bonding structures may be formed on the exposed metallization structures on the sidewalls of the stacklets. In the device 650, there are two distinct orientations of metal lines in a single package. The original horizontal orientation of metal lines in the stacklets becomes a vertical orientation of metal lines (e.g., indicated by arrow V) in the device 650 while the subsequently bonded layers have a horizontal orientation of metal lines (e.g., indicated by arrow H).

In some embodiments, instead of or in addition to layer transferring and/or hybrid bonding, after the surface of a tilt-processed reconstituted wafer is suitably prepared, thin film transistor material may be utilized to make connections between two or more stacklets. For example, any suitable package-level techniques may be utilized to add the thin film transistor material to the tilt-processed reconstituted wafer. Metal may be exposed on sidewalls of the stacklets for connections to the thin film materials. Additionally, or alternatively, via forming techniques may be utilized through sidewalls of the stacklets for connections to the thin film materials.

In some embodiments, ICs with SSICs as described herein may be integrated into a low-temperature system. Lower temperatures enhance conduction in many materials and can enable the use of, e.g., different materials and structures (such as smaller transistor channels). A number of structures may be used to lower the system temperature and so allow for the use of, e.g., smaller conducting structures. Active cooling structures can be used to lower system temperatures to below ambient temperature, even to well below ambient temperature. Active cooling structures can include thermoelectric coolers. In some embodiments, active cooling structures include stacks of alternating p- and n-type semiconductor materials. In some embodiments, active cooling structures flow cooling fluids through channels, including microchannels, thermally coupled to IC packages. In some embodiments, active cooling structures include channels thermally coupled to IC devices 100, 200, 330, 400, 500, 600, 650, 702. In some embodiments, active cooling structures include channels on one or more sides of IC devices 100, 200, 330, 400, 500, 600, 650, 702. In some embodiments, active cooling structures include channels within IC devices 100, 200, 330, 400, 500, 600, 650, 702. In some embodiments, active cooling structures include two-phase cooling. In some embodiments, active cooling structures include low-boiling-point fluids. In some embodiments, active cooling structures include refrigerants as cooling fluids. In some embodiments, active cooling structures lower system temperatures to below 0° C.

FIG. 7 illustrates a cross-sectional view of a low-temperature IC system 700 using die- and package-level active cooling, that may be incorporated into a tilt-processed reconstituted wafer with SSICs in accordance with some embodiments. In the example of IC system 700, IC device 702 includes active-cooling structures or components as provided by both die-level microchannels 777 and package-level active-cooling structure 788. IC system 700 includes a lateral surface along the x-y plane that may be defined or taken at any vertical position of IC system 700. The lateral surface of the x-y plane is orthogonal to a vertical or build-up dimension as defined by the z-axis. In some embodiments, IC system 700 may be formed from any substrate material suitable for the fabrication of transistor circuitry. In some embodiments, a semiconductor substrate is used to manufacture SSICs and other transistors and components of IC system 700. The semiconductor substrate may include a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials, such as gallium arsenide. The substrate may also include semiconductor materials, metals, dielectrics, dopants, and other materials commonly found in semiconductor substrates.

In FIG. 7, IC system 700 includes an IC device 702, which is a monolithic IC with logic/circuitry/interconnects as described herein, including front-side metallization layers 704 (or front-side interconnect layers), and optional back-side metallization layers 705 (or back-side interconnect layers). As shown, IC device 702 may include logic/circuitry/interconnects embedded within front-side layers and/or back-side layers (the detailed structure of the logic/circuitry/interconnects is omitted from the cross-section of FIG. 7 to avoid obscuring the figure). In some embodiments, front-side metallization layers 704 (including further SSICs) provide signal routing to the non-planar transistors and back-side metallization layers 705 provide power delivery, as enabled by through-contacts 714, and vias. In some embodiments, IC system 700 further includes a package-level cooling structure 788, which may be deployed on or over front-side metallization layers 704 (as shown) or on or over a back-side of IC device 702. In some embodiments, package-level cooling structure 788 is coupled to IC device 702 by an adhesion layer 716. IC system 700 may also be deployed without back-side metallization layers 705 shown in FIG. 7. In such embodiments, signal routing and power are provided to circuits of the IC device 702 via front-side metallization layers 704. However, use of back-side metallization layers 705 may offer advantages.

The circuits of the IC device 702 are connected and thermally coupled by metallization, e.g., metal heat spreader 744, to the entire metallization structure by through-contacts 714. In this way, circuits of the IC device 702 are thermally coupled to both the die-level active-cooling structures (of die-level microchannels 777) and package-level active-cooling structure 788.

Interconnectivity of transistors, signal routing to and from circuitry of the IC device 702, metallization interconnects 751, vias 752 (e.g., and other vias), etc., power delivery to circuitry of the IC device 702, etc., and routing to an outside device (not shown), is provided by front-side metallization layers 704, optional back-side metallization layers 705, and package-level interconnects 706. In the example of FIG. 7, package-level interconnects 706 are provided on or over a back-side of IC device 702 as bumps over a passivation layer 755, and IC system 700 is attached to a substrate (and coupled to signal routing to, power delivery, etc.) by package-level interconnects 706. However, package-level interconnects 706 may be provided using any suitable interconnect structures such as bond pads, solder bumps, etc. Furthermore, in some embodiments, package-level interconnects 706 are provided on or over a front-side of IC device 702 (i.e., over front-side metallization layers 704) and package-level cooling structure 788 is provided on or over a back-side of IC device 702.

In IC system 700, IC device 702 includes die-level, active-cooling as provided by die-level microchannels 777. Die-level microchannels 777 are to convey a heat transfer fluid therein to remove heat from IC device 702. The heat transfer fluid may be any suitable liquid or gas. In some embodiments, the heat transfer fluid is liquid nitrogen operable to lower the temperature of IC device 702 to a temperature at or below about −196° C. In some embodiments, the heat transfer fluid is a fluid with a cryogenic temperature operating window (e.g., about −180° C. to about −70° C.). In some embodiments, the heat transfer fluid is one of helium-3, helium-4, hydrogen, neon, air, fluorine, argon, oxygen, or methane.

As used herein, the term “microchannels” indicates a channel to convey a heat transfer fluid with the multiple microchannels providing discrete separate channels or a network of channels. Notably, the plural microchannels does not indicate separate channel networks are needed. Such die-level microchannels 777 may be provided in any pattern in the x-y plane such as serpentine patterns, patterns of multiple parallel die-level microchannels 777, or the like. Die-level microchannels 777 couple to a heat exchanger (not shown) that removes heat from and cools the heat transfer fluid before re-introduction to die-level microchannels 777. The flow of fluid within die-level microchannels 777 may be provided by a pump or other fluid flow device. The operation of the heat exchanger, pump, etc. may be controlled by a controller.

In the illustrated embodiment, die-level microchannels 777 are implemented at metallization level M12. In other embodiments, die-level microchannels 777 are implemented over metallization level M12. Die-level microchannels 777 may be formed using any suitable technique or techniques such as patterning and etch techniques to form the void structures of die-level microchannels 777 and passivation or deposition techniques to form a cover structure 778 to enclose the void structures. As shown, in some embodiments, the die-level, active-cooling structure of IC system 700 includes a number of die-level microchannels 777 in IC device 702 and over a number of front-side metallization layers 704. As discussed, die-level microchannels 777 are to convey a heat transfer fluid therein. In some embodiments, a metallization feature 779 of metallization layer M12 is laterally adjacent to die-level microchannels 777. For example, metallization feature 779 may couple to a package-level interconnect structure (not shown) for signal routing for IC device 702. In some embodiments, a passive heat removal device such as a heat sink or the like may be used instead of or in addition to package-level cooling structure 788. In some embodiments, package-level cooling structure 788 is not deployed in IC system 700.

As used herein, the term “metallization layer” describes layers with interconnections or wires that provide electrical routing, generally formed of metal or other electrically and thermally conductive material. Adjacent metallization layers may be formed of different materials and by different methods. Adjacent metallization layers, such as metallization interconnects 751, are interconnected by vias, such as vias 752, that may be characterized as part of the metallization layers or between the metallization layers. As shown, in some embodiments, front-side metallization layers 704 are formed over and immediately adjacent transistors. The back-side is then the opposite side, which may be exposed during processing by attaching the front-side to a carrier wafer and exposing the back-side (e.g., by back-side grind or etch operations) as known in the art.

In the illustrated example, front-side metallization layers 704 include M0, V0, M1, M2/V1, M3/V2, M4/V3, and M4-M12. However, front-side metallization layers 704 may include any number of metallization layers such as eight or more metallization layers. Similarly, back-side metallization layers 705 include BM0, BM1, BM2, and BM3. However, back-side metallization layers 705 may include any number of metallization layers such as two to five metallization layers. Front-side metallization layers 704 and back-side metallization layers 705 are embedded within dielectric materials. Furthermore, optional metal-insulator-metal (MIM) devices such as diode devices may be provided within back-side metallization layers 705. Other devices such as capacitive memory devices may be provided within front-side metallization layers 704 and/or back-side metallization layers 705.

IC system 700 includes package-level active-cooling structure 788 having package-level microchannels 789. Package-level microchannels 789 are to convey a heat transfer fluid therein to remove heat from IC device 702. The heat transfer fluid may be any suitable liquid or gas as discussed with respect to die-level microchannels 777. Package-level microchannels 789 may be provided in any pattern in the x-y plane such as serpentine patterns, patterns of multiple parallel package-level microchannels 789, etc. Package-level microchannels 789 couple to a heat exchanger (not shown) that removes heat from and cools the heat transfer fluid before re-introduction to package-level microchannels 789. The flow of fluid within package-level microchannels 789 may be provided by a pump or other fluid-flow device. The operation of the heat exchanger, pump, etc. may be controlled by a controller. In the illustrated embodiment, package-level active-cooling structure 788 is a chiller mounted to IC device 702 such that the chiller has a solid body having microchannels therein to convey a heat transfer fluid.

In some embodiments, the heat-removal fluid deployed in die-level microchannels 777 and package-level active-cooling structure 788 are coupled to the same pump and heat exchanger systems. In such embodiments, the heat removal fluid conveyed in both die-level microchannels 777 and package-level active-cooling structure 788 are the same material. Such embodiments may advantageously provide simplicity. In other embodiments, the heat removal fluids are controlled separately. In such embodiments, the heat removal fluids conveyed by die-level microchannels 777 and package-level active-cooling structure 788 may be the same or they may be different. Such embodiments may advantageously provide improved flexibility.

As discussed, IC system 700 includes IC device 702 and optional die-level and package-level active-cooling structures operable to remove heat from IC device 702 to achieve a very low operating temperature of IC device 702. As used herein, the term “very low operating temperature” indicates a temperature at or below 0° C., although even lower temperatures such as an operating temperature at or below −50° C., an operating temperature at or below −70° C., an operating temperature at or below −100° C., an operating temperature at or below −180° C., or an operating temperature at or below −196° C. may be used. In some embodiments, the operating temperature is in a cryogenic temperature operating window (e.g., about −180° C. to about −70° C.). The active-cooling structure may be provided as a package-level structure (i.e., separable from IC device 702), as a die-level structure (i.e., integral to IC device 702), or both. In some embodiments, IC device 702 is deployed in a cold environment, formed using sufficiently conductive materials, etc. and an active-cooling structure is not used.

FIG. 8 illustrates a view of an example two-phase immersion cooling system 800 for low-temperature operation of an IC device, in accordance with some embodiments. As shown, two-phase immersion cooling system 800 includes a fluid containment structure 801, a low-boiling point liquid 802 within fluid containment structure 801, and a condensation structure 803 at least partially within fluid containment structure 801. As used herein, the term “low-boiling point liquid” indicates a liquid having a boiling point in the very low temperature ranges discussed. In some embodiments, the low-boiling point liquid is one of helium-3, helium-4, hydrogen, neon, air, fluorine, argon, oxygen, or methane.

In operation, a heat generation source 804, such as an IC package including any of IC devices or systems 100, 200, 300, 400, 500, 600, 650, 700 as discussed herein is immersed in low-boiling point liquid 802. In some embodiments, IC devices or systems 100, 200, 300, 400, 500, 600, 650, 700 as deployed in two-phase immersion cooling system 800 do not include additional active cooling structures, although such die-level or package-level active cooling structures may be used in concert with two-phase immersion cooling system 800. In some embodiments, when deployed in two-phase immersion cooling system 800, package-level active-cooling structure 788 is a heat sink, a heat dissipation plate, a porous heat dissipation plate or the like.

Notably, IC device 702 (or IC device 100, 200, 330, 400, 500, 600, 650), is the source of heat in the context of two-phase immersion cooling system 800. For example, IC device 702 may be packaged and mounted on electronics substrate 805. Electronic substrate 805 may be coupled to a power supply (not shown) and may be partially or completely submerged in low-boiling point liquid 802.

In operation, the heat produced by heat generation source 804 vaporizes low-boiling point liquid 802 as shown in vapor or gas state as bubbles 806, which may collect, due to gravitational forces, above low-boiling point liquid 802 as a vapor portion 807 within fluid containment structure 801. Condensation structure 803 may extend through vapor portion 807. In some embodiments, condensation structure 803 is a heat exchanger having a number of tubes 808 with a cooling fluid (i.e., a fluid colder than the condensation point of vapor portion 807) shown by arrows 809 that may flow through tubes 808 to condense vapor portion 807 back to low-boiling point liquid 802. In the IC system of FIG. 8, package-level active-cooling structure 788 includes a passive cooling structure such as a heat sink for immersion in low-boiling point liquid 802.

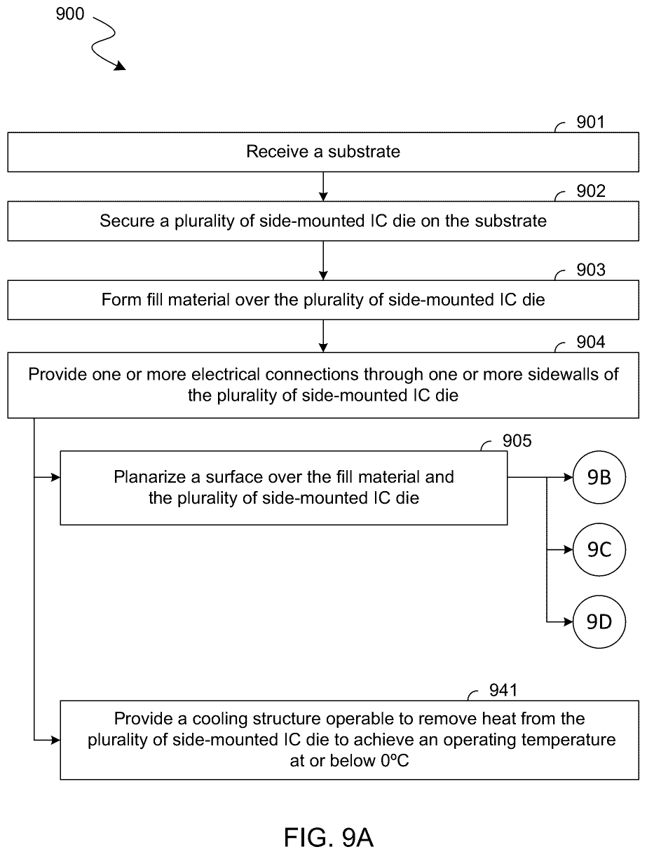

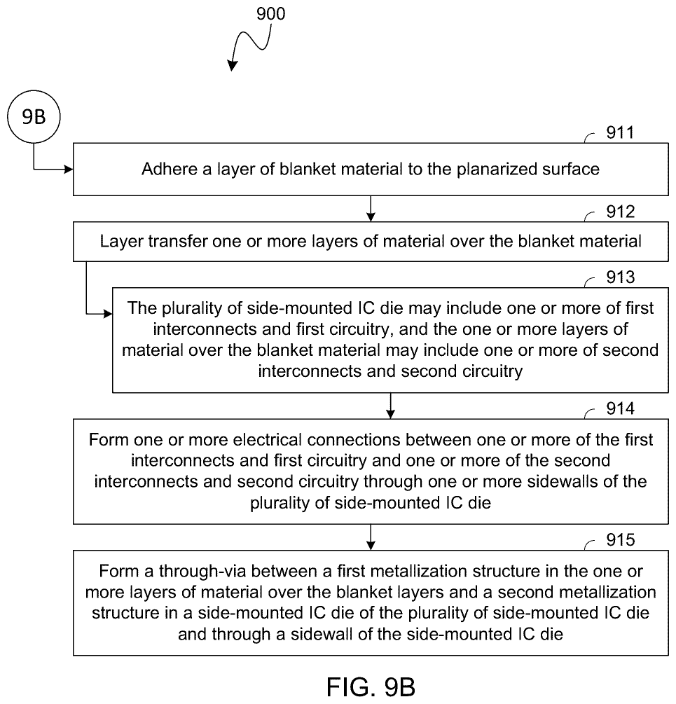

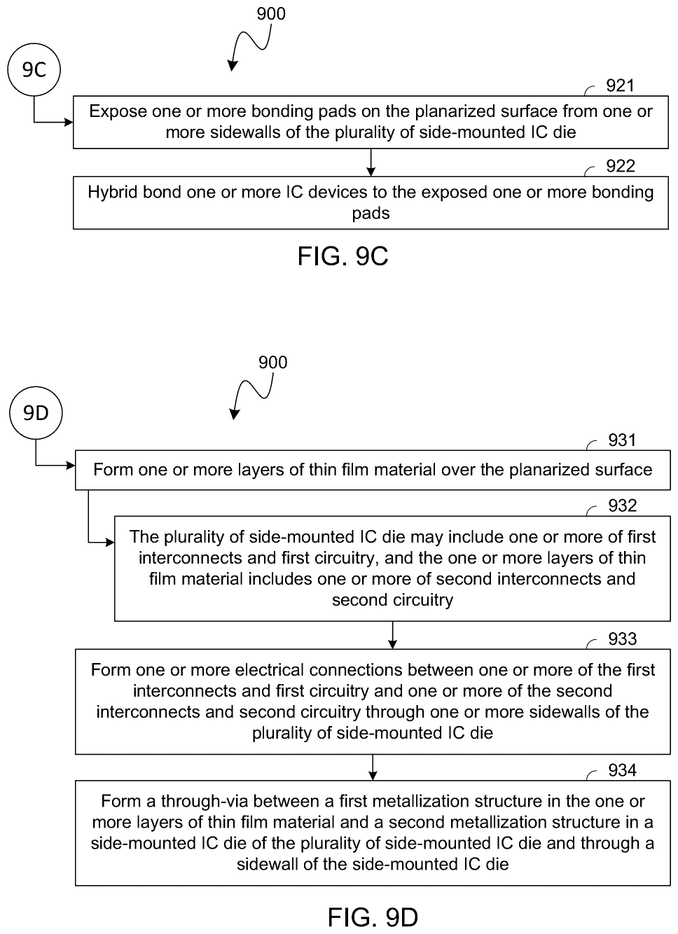

FIGS. 9A to 9D illustrate various processes or methods 900 for forming SSICs on an IC device, in accordance with some embodiments. FIGS. 9A to 9D show methods 900 that includes operations 901-934. Some operations shown in FIGS. 9A to 9D are optional. FIGS. 9A to 9D show an example sequence, but the operations can be done in other sequences as well, and some operations may be omitted. Some operations can also be performed multiple times before other operations are performed. Some operations may be included within other operations. Methods 900 generally entail arranging a plurality of IC die on their sides in a reconstituted wafer, and further processing the IC die through their sidewalls to provide electrical connectivity to the IC die.

In operation 901, a substrate is received. The substrate is a planar platform and may already include dielectric and metallization structures. The substrate may be one of many layers in an IC device, and may itself have many layers. The substrate may be above other layers in the IC device (all or of a portion of which may be subsequently removed in back-side metallization contexts), and other layers may subsequently be formed in or over the substrate. In some embodiments, SSICs will be bonded on a frontside of the substrate. In some embodiments, SSICs will be bonded on a backside of the substrate. In some embodiments, SSICs will be bonded on both sides.

The substrate may include any suitable material or materials. Any suitable semiconductor or other material can be used. Transistors in the IC device may be of the same material as the substrate or, e.g., deposited on the substrate. The substrate may include a semiconductor material that transistors can be formed out of and on, including a crystalline material. In some examples, the substrate may include monocrystalline silicon (Si), germanium (Ge), silicon germanium (SiGe), a III-V alloy material (e.g., gallium arsenide (GaAs)), a silicon carbide (SiC), a sapphire (Al₂O₃), or any combination thereof. In some embodiments, the substrate includes crystalline silicon and subsequent components are also silicon.

In operation 902, a plurality of side-mounted IC die are secured on the substrate. In operation 903, fill material is formed over the plurality of side-mounted IC die. In operation 904, one or more electrical connections are provided through one or more sidewalls of the plurality of side-mounted IC die.

Each of the side-mounted IC die may include transistors, resistors, and interconnections, e.g., between them and with external structures, including power, signal, data, ground, etc. lines. At least some of these structures may be conventional and known methods may be used. Transistors in the side-mounted IC die can be formed from the same material as the substrate or, e.g., deposited on the side-mounted IC die substrate. In some embodiments, the side-mounted IC die substrate is crystalline silicon and transistors in the first layer are formed by etching back the substrate to form transistor structures, e.g., non-planar structures, such as fins for access transistor channels. In some embodiments, transistors comprise polycrystalline silicon, which may be deposited over other materials. Other semiconductor materials may be deposited as well, on the side-mounted IC die substrate or over other structures on the side-mounted IC die substrate. Such semiconductor materials can be any material suitable for forming a transistor channel, e.g., for an access transistor, but some materials will be preferred for their manufacturing properties, e.g., the capability to be deposited easily, in a well-controlled manner, and in thin layers.

Forming the transistors in the side-mounted IC die may include forming ultrathin structures, such as nanowires, nanoribbons, or nanosheets, for transistor channels. In some embodiments, one or a few monolayers of semiconductor materials are deposited over the side-mounted IC die substrate or other structures. In some embodiments, less than 2 nm of semiconductor material is deposited as a film. In some embodiments, a transition-metal dichalcogenide (TMD) material is deposited to form access transistors. TMDs can be 2D materials, e.g., forming monolayers of semiconductor materials. 2D materials may be deposited on structures, such as backbone features, deposited on the side-mounted IC die substrate.

The methods for forming transistors may vary with transistor function. TFTs for use as pull-up transistors may be formed as parasitic devices deposited over other structures in some layers of the side-mounted IC die. In some embodiments, forming transistors includes depositing amorphous or polycrystalline metal oxides. In some embodiments, a thin, metal-oxide film is deposited that may be semiconducting substantially as-deposited, and/or following some subsequent activation process, such as a thermal anneal.

Other structures, e.g., resistors and metallization, may also be deposited or otherwise formed from such materials, and such forming may be done throughout the forming operations of transistors and other structures. Pull-up resistors may be formed from the side-mounted IC die substrate material or, e.g., by depositing polycrystalline silicon or other material over the side-mounted IC die substrate. Other structures, e.g., access transistor gate electrodes, may be formed such that convenient connections can be made to associated structures in the first layer. Metallization may be formed before and after, and interleaved throughout, the forming of other structures.

In operation 905, a surface is planarized over the fill material and the plurality of side-mounted IC die. In some embodiments, after the surface is planarized (e.g., and/or polished as needed), a layer transfer process may be utilized to add further layers of material over the SSIC die. For example, in operation 911, a layer of blanket material is adhered to the planarized surface and, in operation 912, one or more layers of material are layer transferred over the blanket material. In some embodiments, the plurality of side-mounted IC die may include one or more of first interconnects and first circuitry, and the one or more layers of material over the blanket material may include one or more of second interconnects and second circuitry (at box 913). In operation 914, one or more electrical connections are formed between one or more of the first interconnects and first circuitry and one or more of the second interconnects and second circuitry through one or more sidewalls of the plurality of side-mounted IC die. For example, in operation 915, a through-via is formed between a first metallization structure in the one or more layers of material over the blanket layers and a second metallization structure in a side-mounted IC die of the plurality of side-mounted IC die and through a sidewall of the side-mounted IC die.

In some embodiments, after the surface is planarized (e.g., and/or polished as needed), a hybrid bonding process may be utilized to add further layers of material over the SSIC die. For example, in operation 921, one or more bonding pads are exposed on the planarized surface from one or more sidewalls of the plurality of side-mounted IC die and, in operation 922, one or more IC devices are hybrid bonded to the exposed one or more bonding pads.

In some embodiments, after the surface is planarized (e.g., and/or polished as needed), a thin film process may be utilized to add further layers of material over the SSIC die. For example, in operation 931, one or more layers of thin film material are formed over the planarized surface. In some embodiments, the plurality of side-mounted IC die may include one or more of first interconnects and first circuitry, and the one or more layers of thin film material includes one or more of second interconnects and second circuitry (at box 932). In operation 933, one or more electrical connections are formed between one or more of the first interconnects and first circuitry and one or more of the second interconnects and second circuitry through one or more sidewalls of the plurality of side-mounted IC die. For example, in operation 934, a through-via is formed between a first metallization structure in the one or more layers of thin film material and a second metallization structure in a side-mounted IC die of the plurality of side-mounted IC die and through a sidewall of the side-mounted IC die.

In operation 941, a cooling structure is provided operable to remove heat from the plurality of side-mounted IC die to achieve an operating temperature at or below 0° C.

In some embodiments, two circuits or signals (and more) are formed in vertically adjacent layers where in different metallization layers are connected between layers by forming a vertical metallization structure, e.g., a metallized via connection, on one side of the layers, beyond the horizontal edges or boundaries of the circuits. In some such embodiments, a deep border via connects the different metallization layers. In some embodiments, two of these connected circuits are vertically aligned, and other connected circuits in both layers are not vertically aligned. The vertical metallization structure, e.g., a via, can be formed as part of traditional or other methods, e.g. single or dual damascene techniques, etc.

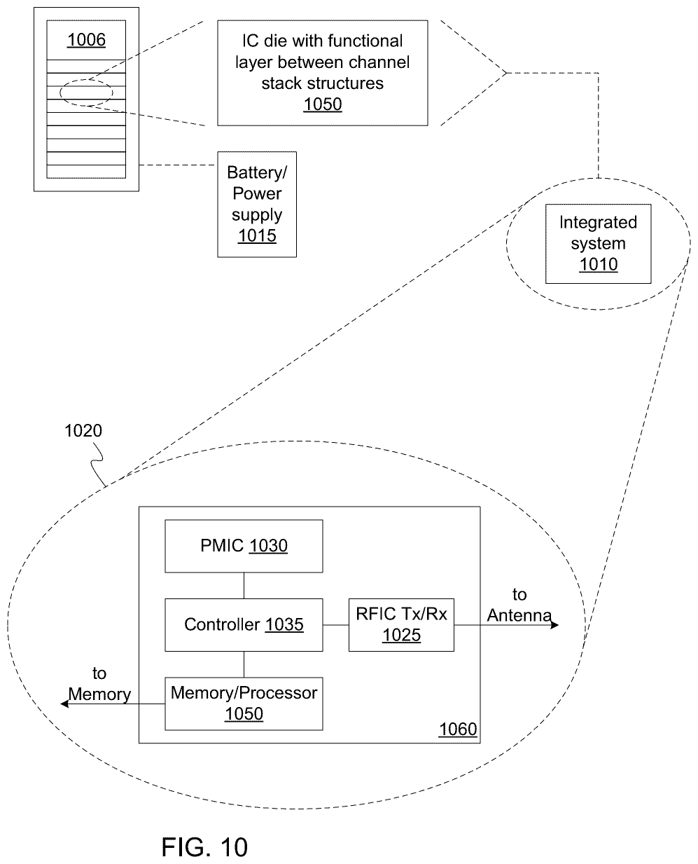

FIG. 10 illustrates a diagram of an example data server machine 1006 employing an IC device with SSICs as described herein, in accordance with some embodiments. Server machine 1006 may be any commercial server, for example, including any number of high-performance computing platforms disposed within a rack and networked together for electronic data processing, which in the exemplary embodiment includes one or more devices 1050 having SSICs.

Also as shown, server machine 1006 includes a battery and/or power supply 1015 to provide power to devices 1050, and to provide, in some embodiments, power delivery functions such as power regulation. Devices 1050 may be deployed as part of a package-level integrated system 1010. Integrated system 1010 is further illustrated in the expanded view 1020. In the exemplary embodiment, devices 1050 (labeled “Memory/Processor”) includes at least one memory chip (e.g., RAM), and/or at least one processor chip (e.g., a microprocessor, a multi-core microprocessor, or graphics processor, or the like) having the characteristics discussed herein. In an embodiment, device 1050 is a microprocessor including a cache memory. As shown, device 1050 may be a multi-chip module employing one or more IC devices with SSICs, as discussed herein. Device 1050 may be further coupled to (e.g., communicatively coupled to) a board, an interposer, or a substrate 1060 along with, one or more of a power management IC (PMIC) 1030, RF (wireless) IC (RFIC) 1025, including a wideband RF (wireless) transmitter and/or receiver (TX/RX) (e.g., including a digital baseband and an analog front end module further comprises a power amplifier on a transmit path and a low noise amplifier on a receive path), and a controller 1035 thereof. In some embodiments, RFIC 1025, PMIC 1030, controller 1035, and device 1050 include IC devices having SSICs on substrate 1060 in a multi-chip module.

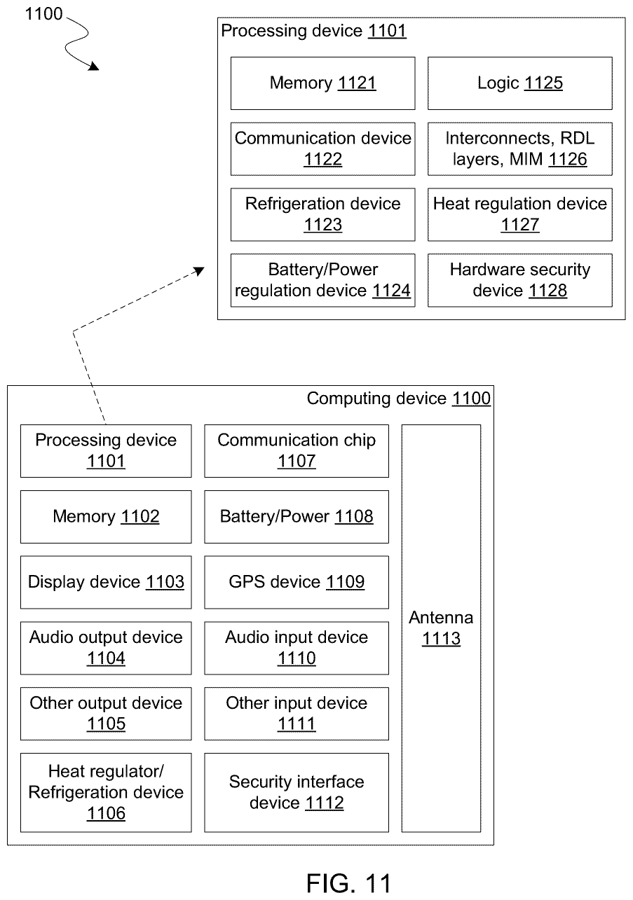

FIG. 11 is a block diagram of an example computing device 1100, in accordance with some embodiments. For example, one or more components of computing device 1100 may include any of the devices or structures discussed herein. A number of components are illustrated in FIG. 11 as being included in computing device 1100, but any one or more of these components may be omitted or duplicated, as suitable for the application. In some embodiments, some or all of the components included in computing device 1100 may be attached to one or more printed circuit boards (e.g., a motherboard). In some embodiments, various ones of these components may be fabricated onto a single system-on-a-chip (SoC) die. Additionally, in various embodiments, computing device 1100 may not include one or more of the components illustrated in FIG. 11, but computing device 1100 may include interface circuitry for coupling to the one or more components. For example, computing device 1100 may not include a display device 1103, but may include display device interface circuitry (e.g., a connector and driver circuitry) to which display device 1103 may be coupled. In another set of examples, computing device 1100 may not include an audio output device 1104, other output device 1105, global positioning system (GPS) device 1109, audio input device 1110, or other input device 1111, but may include audio output device interface circuitry, other output device interface circuitry, GPS device interface circuitry, audio input device interface circuitry, audio input device interface circuitry, to which audio output device 1104, other output device 1105, GPS device 1109, audio input device 1110, or other input device 1111 may be coupled.

Computing device 1100 may include a processing device 1101 (e.g., one or more processing devices). As used herein, the term “processing device” or “processor” indicates a device that processes electronic data from registers and/or memory to transform that electronic data into other electronic data that may be stored in registers and/or memory. Processing device 1101 may include a memory 1121, a communication device 1122, a refrigeration device 1123, a battery/power regulation device 1124, logic 1125, interconnects 1126 (i.e., optionally including redistribution layers (RDL) or metal-insulator-metal (MIM) devices), a heat regulation device 1127, and a hardware security device 1128.

Processing device 1101 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 1100 may include a memory 1102, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1102 includes memory that shares a die with processing device 1101. This memory may be used as cache memory and may include embedded dynamic random-access memory (eDRAM) or spin transfer torque magnetic random-access memory (STT-M RAM).

Computing device 1100 may include a heat regulation/refrigeration device 1106. Heat regulation/refrigeration device 1106 may maintain processing device 1101 (and/or other components of computing device 1100) at a predetermined low temperature during operation. This predetermined low temperature may be any temperature discussed herein.

In some embodiments, computing device 1100 may include a communication chip 1107 (e.g., one or more communication chips). For example, the communication chip 1107 may be configured for managing wireless communications for the transfer of data to and from computing device 1100. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 1107 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1107 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1107 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1107 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1107 may operate in accordance with other wireless protocols in other embodiments. Computing device 1100 may include an antenna 1113 to facilitate wireless communications and/or to receive other wireless communications (such as AM or FM radio transmissions).

In some embodiments, communication chip 1107 may manage wired communications, such as electrical, optical, or any other suitable communication protocols (e.g., the Ethernet). As noted above, communication chip 1107 may include multiple communication chips. For instance, a first communication chip 1107 may be dedicated to shorter-range wireless communications such as Wi-Fi or Bluetooth, and a second communication chip 1107 may be dedicated to longer-range wireless communications such as GPS, EDGE, GPRS, CDMA, WiMAX, LTE, EV-DO, or others. In some embodiments, a first communication chip 1107 may be dedicated to wireless communications, and a second communication chip 1107 may be dedicated to wired communications.

Computing device 1100 may include battery/power circuitry 1108. Battery/power circuitry 1108 may include one or more energy storage devices (e.g., batteries or capacitors) and/or circuitry for coupling components of computing device 1100 to an energy source separate from computing device 1100 (e.g., AC line power).

Computing device 1100 may include a display device 1103 (or corresponding interface circuitry, as discussed above). Display device 1103 may include any visual indicators, such as a heads-up display, a computer monitor, a projector, a touchscreen display, a liquid crystal display (LCD), a light-emitting diode display, or a flat panel display, for example.

Computing device 1100 may include an audio output device 1104 (or corresponding interface circuitry, as discussed above). Audio output device 1104 may include any device that generates an audible indicator, such as speakers, headsets, or earbuds, for example.

Computing device 1100 may include an audio input device 1110 (or corresponding interface circuitry, as discussed above). Audio input device 1110 may include any device that generates a signal representative of a sound, such as microphones, microphone arrays, or digital instruments (e.g., instruments having a musical instrument digital interface (MIDI) output).

Computing device 1100 may include a GPS device 1109 (or corresponding interface circuitry, as discussed above). GPS device 1109 may be in communication with a satellite-based system and may receive a location of computing device 1100, as known in the art.

Computing device 1100 may include other output device 1105 (or corresponding interface circuitry, as discussed above). Examples of the other output device 1105 may include an audio codec, a video codec, a printer, a wired or wireless transmitter for providing information to other devices, or an additional storage device.

Computing device 1100 may include other input device 1111 (or corresponding interface circuitry, as discussed above). Examples of the other input device 1111 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1100 may include a security interface device 1112. Security interface device 1112 may include any device that provides security measures for computing device 1100 such as intrusion detection, biometric validation, security encode or decode, access list management, malware detection, or spyware detection.

Computing device 1100, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1-11. The subject matter may be applied to other deposition applications, as well as any appropriate manufacturing application, as will be understood to those skilled in the art.

The following examples pertain to further embodiments, and specifics in the examples may be used anywhere in one or more embodiments.

Example 1 includes an IC device, comprising a first IC die with a first front surface, a first back surface, and a first side surface along opposed edges of the first front surface and the first back surfaces of the first IC die, a second IC die with a second front surface, a second back surface, and a second side surface along opposed edges of the second front surface and second back surface of the second IC die, a substrate coupled to the first side surface of the first IC die and the second side surface of the second IC die, and fill material between one of the first front surface and the first back surface of the first IC die and one of the second front surface and the second back surface of the second IC die.

Example 2 includes the IC device of Example 1, further comprising a first electrical connection through a third side surface along opposed edges of the first front surface and the first back surfaces of the first IC die opposite to the first side surface of the first IC die coupled to the substrate.

Example 3 includes the IC device of Example 2, further comprising a second electrical connection through a fourth side surface along opposed edges of the second front surface and the second back surfaces of the second IC die opposite to the second side surface of the second IC die coupled to the substrate, and conductive material over the third side of the first IC die and the fourth side of the second IC die that couples the first electrical connection to the second electrical connection.

Example 4 includes the IC device of Example 3, wherein the conductive material is layer transferred over the third side of the first IC die and the fourth side of the second IC die.

Example 5 includes the IC device of Example 3, wherein the conductive material is hybrid bonded over the third side of the first IC die and the fourth side of the second IC die.

Example 6 includes the IC device of Example 3, wherein the conductive material is thin film processed over the third side of the first IC die and the fourth side of the second IC die.

Example 7 includes a system, comprising a power supply, an IC device coupled to the power supply, the IC device comprising a reconstituted wafer with a plurality of IC die coupled to a substrate of the reconstituted wafer on respective first sidewalls of the plurality of IC die, and one or more interconnect layers over the reconstituted wafer, wherein the one or more interconnect layers provide one or more electrical connections between two or more IC die of the plurality of IC die through respective second sidewalls of the plurality of IC die opposite to the first sidewalls.

Example 8 includes the system of Example 7, wherein the one or more interconnect layers are layer transferred over the reconstituted wafer.

Example 9 includes the system of Example 7, wherein the one or more interconnect layers are hybrid bonded over the reconstituted wafer.

Example 10 includes the system of Example 7, wherein the one or more interconnect layers are thin film processed over the reconstituted wafer.

Example 11 includes the system of any of Examples 7 to 10, wherein the IC device comprises a wafer-scale engine.

Example 12 includes the system of any of Examples 7 to 11, further comprising a cooling structure coupled to the IC device operable to remove heat from the IC device to achieve an operating temperature below 0° C.

Example 13 includes the system of Example 12, wherein the cooling structure is further operable to remove heat from the IC device to achieve an operating temperature at or below −25° C.

Example 14 includes the system of any of Examples 12 to 13, wherein the cooling structure is over the IC device.

Example 15 includes the system of Example 14, wherein the cooling structure comprises a plurality of microchannels in the IC device and over the reconstituted wafer, the microchannels to convey a heat transfer fluid therein.

Example 16 includes the system of Example 15, wherein the cooling structure further comprises a chiller mounted to the IC device over the microchannels, the chiller comprising one of a solid body comprising second microchannels to convey a second heat transfer fluid therein or a heat sink for immersion in a low-boiling point liquid.

Example 17 includes the system of any of Examples 15 to 16, wherein the cooling structure is further to convey liquid nitrogen to achieve an operating temperature at or below about −196° C.

Example 18 includes a method, comprising receiving a substrate, securing a plurality of side-mounted IC die on the substrate, forming fill material over the plurality of side-mounted IC die, and providing one or more electrical connections through one or more sidewalls of the plurality of side-mounted IC die.

Example 19 includes the method of Example 18, further comprising planarizing a surface over the fill material and the plurality of side-mounted IC die.

Example 20 includes the method of Example 19, further comprising adhering a layer of blanket material to the planarized surface, and layer transferring one or more layers of material over the blanket material.

Example 21 includes the method of Example 20, wherein the plurality of side-mounted IC die includes one or more of first interconnects and first circuitry, and wherein the one or more layers of material over the blanket material includes one or more of second interconnects and second circuitry. further comprising forming one or more electrical connections between one or more of the first interconnects and first circuitry and one or more of the second interconnects and second circuitry through one or more sidewalls of the plurality of side-mounted IC die.

Example 22 includes the method of Example 21, further comprising forming a through-via between a first metallization structure in the one or more layers of material over the blanket layers and a second metallization structure in a side-mounted IC die of the plurality of side-mounted IC die and through a sidewall of the side-mounted IC die.

Example 23 includes the method of Example 19, further comprising exposing one or more bonding pads on the planarized surface from one or more sidewalls of the plurality of side-mounted IC die, and hybrid bonding one or more IC devices to the exposed one or more bonding pads.

Example 24 includes the method of Example 19, further comprising forming one or more layers of thin film material over the planarized surface.

Example 25 includes the method of Example 24, wherein the plurality of side-mounted IC die includes one or more of first interconnects and first circuitry, and wherein the one or more layers of thin film material includes one or more of second interconnects and second circuitry, further comprising forming one or more electrical connections between one or more of the first interconnects and first circuitry and one or more of the second interconnects and second circuitry through one or more sidewalls of the plurality of side-mounted IC die.

Example 26 includes the method of Example 25, further comprising forming a through-via between a first metallization structure in the one or more layers of thin film material and a second metallization structure in a side-mounted IC die of the plurality of side-mounted IC die and through a sidewall of the side-mounted IC die.

Example 27 includes the method of any of Examples 18 to 26, further comprising providing a cooling structure operable to remove heat from the plurality of side-mounted IC die to achieve an operating temperature at or below 0° C.

Example 28 includes an apparatus, comprising means for receiving a substrate, means for securing a plurality of side-mounted IC die on the substrate, means for forming fill material over the plurality of side-mounted IC die, and means for providing one or more electrical connections through one or more sidewalls of the plurality of side-mounted IC die.

Example 29 includes the apparatus of Example 28, further comprising means for planarizing a surface over the fill material and the plurality of side-mounted IC die.

Example 30 includes the apparatus of Example 29, further comprising means for adhering a layer of blanket material to the planarized surface, and means for layer transferring one or more layers of material over the blanket material.

Example 31 includes the apparatus of Example 30, wherein the plurality of side-mounted IC die includes one or more of first interconnects and first circuitry, and wherein the one or more layers of material over the blanket material includes one or more of second interconnects and second circuitry. further comprising means for forming one or more electrical connections between one or more of the first interconnects and first circuitry and one or more of the second interconnects and second circuitry through one or more sidewalls of the plurality of side-mounted IC die.

Example 32 includes the apparatus of Example 31, further comprising means for forming a through-via between a first metallization structure in the one or more layers of material over the blanket layers and a second metallization structure in a side-mounted IC die of the plurality of side-mounted IC die and through a sidewall of the side-mounted IC die.

Example 33 includes the apparatus of Example 29, further comprising means for exposing one or more bonding pads on the planarized surface from one or more sidewalls of the plurality of side-mounted IC die, and means for hybrid bonding one or more IC devices to the exposed one or more bonding pads.

Example 34 includes the apparatus of Example 29, further comprising means for forming one or more layers of thin film material over the planarized surface.

Example 35 includes the apparatus of Example 34, wherein the plurality of side-mounted IC die includes one or more of first interconnects and first circuitry, and wherein the one or more layers of thin film material includes one or more of second interconnects and second circuitry, further comprising means for forming one or more electrical connections between one or more of the first interconnects and first circuitry and one or more of the second interconnects and second circuitry through one or more sidewalls of the plurality of side-mounted IC die.

Example 36 includes the apparatus of Example 35, further comprising means for forming a through-via between a first metallization structure in the one or more layers of thin film material and a second metallization structure in a side-mounted IC die of the plurality of side-mounted IC die and through a sidewall of the side-mounted IC die.

Example 37 includes the apparatus of any of Examples 28 to 36, further comprising means for providing a cooling structure operable to remove heat from the plurality of side-mounted IC die to achieve an operating temperature at or below 0° C.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An integrated circuit (IC) device, comprising:
a first IC die with a first front surface, a first back surface, and a first side surface along opposed edges of the first front surface and the first back surfaces of the first IC die;
a second IC die with a second front surface, a second back surface, and a second side surface along opposed edges of the second front surface and second back surface of the second IC die;
a substrate coupled to the first side surface of the first IC die and the second side surface of the second IC die; and
fill material between one of the first front surface and the first back surface of the first IC die and one of the second front surface and the second back surface of the second IC die.

2. The IC device of claim 1, further comprising:
a first electrical connection through a third side surface along opposed edges of the first front surface and the first back surfaces of the first IC die opposite to the first side surface of the first IC die coupled to the substrate.

3. The IC device of claim 2, further comprising:
a second electrical connection through a fourth side surface along opposed edges of the second front surface and the second back surfaces of the second IC die opposite to the second side surface of the second IC die coupled to the substrate; and
conductive material over the third side of the first IC die and the fourth side of the second IC die that couples the first electrical connection to the second electrical connection.

4. The IC device of claim 3, wherein the conductive material is layer transferred over the third side of the first IC die and the fourth side of the second IC die.

5. The IC device of claim 3, wherein the conductive material is hybrid bonded over the third side of the first IC die and the fourth side of the second IC die.

6. The IC device of claim 5, wherein the conductive material is thin film processed over the third side of the first IC die and the fourth side of the second IC die.

7. A system, comprising:
a power supply;
an integrated circuit (IC) device coupled to the power supply, the IC device comprising:
a reconstituted wafer with a plurality of IC die coupled to a substrate of the reconstituted wafer on respective first sidewalls of the plurality of IC die; and
one or more interconnect layers over the reconstituted wafer, wherein the one or more interconnect layers provide one or more electrical connections between two or more IC die of the plurality of IC die through respective second sidewalls of the plurality of IC die opposite to the first sidewalls.

8. The system of claim 7, wherein the IC device comprises a wafer-scale engine.

9. The system of claim 7, further comprising:
a cooling structure coupled to the IC device operable to remove heat from the IC device to achieve an operating temperature below 0° C.

10. The system of claim 9, wherein the cooling structure is further operable to remove heat from the IC device to achieve an operating temperature at or below −25° C.

11. The system of claim 9, wherein the cooling structure comprises a plurality of microchannels in the IC device and over the reconstituted wafer, the microchannels to convey a heat transfer fluid therein.

12. The system of claim 11, wherein the cooling structure further comprises a chiller mounted to the IC device over the microchannels, the chiller comprising one of a solid body comprising second microchannels to convey a second heat transfer fluid therein or a heat sink for immersion in a low-boiling point liquid.

13. The system of claim 11, wherein the cooling structure is further to convey liquid nitrogen to achieve an operating temperature at or below about −196° C.

14. A method, comprising:
receiving a substrate;
securing a plurality of side-mounted integrated circuit (IC) die on the substrate;
forming fill material over the plurality of side-mounted IC die; and
providing one or more electrical connections through one or more sidewalls of the plurality of side-mounted IC die.

15. The method of claim 14, further comprising:
planarizing a surface over the fill material and the plurality of side-mounted IC die.

16. The method of claim 15, further comprising:
adhering a layer of blanket material to the planarized surface; and
layer transferring one or more layers of material over the blanket material.

17. The method of claim 16, wherein the plurality of side-mounted IC die includes one or more of first interconnects and first circuitry, and wherein the one or more layers of material over the blanket material includes one or more of second interconnects and second circuitry. further comprising:
forming one or more electrical connections between one or more of the first interconnects and first circuitry and one or more of the second interconnects and second circuitry through one or more sidewalls of the plurality of side-mounted IC die.

18. The method of claim 17, further comprising:
forming a through-via between a first metallization structure in the one or more layers of material over the blanket layers and a second metallization structure in a side-mounted IC die of the plurality of side-mounted IC die and through a sidewall of the side-mounted IC die.

19. The method of claim 15, further comprising:
exposing one or more bonding pads on the planarized surface from one or more sidewalls of the plurality of side-mounted IC die; and
hybrid bonding one or more IC devices to the exposed one or more bonding pads.

20. The method of claim 15, further comprising:
forming one or more layers of thin film material over the planarized surface.
